(19) United States
(12) Patent Application Publication
(10) Pub. No.: US 2014/0145345 A1
(43) Pub. Date: May 29, 2014

(54) METHOD OF FORMING A SEMICONDUCTOR STRUCTURE, AND A SEMICONDUCTOR STRUCTURE

(71) Applicant: INFINEON TECHNOLOGIES AG, Neubiberg (DE)

(72) Inventors: Helmut Brunner, Feistritz/Drau (AT); Joachim Hirschler, Villach (AT)

(73) Assignee: INFINEON TECHNOLOGIES AG, Neubiberg (DE)

(21) Appl. No.: 13/685,748

(22) Filed: Nov. 27, 2012

(51) Int. Cl. H01L 23/538; H01L 21/48

(52) U.S. Cl. CPC H01L 23/5384; H01L 21/486
USPC 257/774; 438/675

(57) ABSTRACT

A method of forming a semiconductor structure in accordance with various embodiments may include: forming at least one opening in a workpiece; forming a first conductive layer within the at least one opening, the first conductive layer not completely filling the at least one opening; forming a fill layer over the first conductive layer within the at least one opening; and forming a second conductive layer over the fill layer.

### TECHNICAL FIELD

Various embodiments relate to a method of forming a semiconductor structure, and a semiconductor structure.

### BACKGROUND

Many semiconductor structures may include conductive interconnects. New ways of making conductive interconnects may be needed.

### SUMMARY

A method of forming a semiconductor structure in accordance with various embodiments may include: forming at least one opening in a workpiece; forming a first conductive layer within the at least one opening, the first conductive layer not completely filling the at least one opening; forming a fill layer over the first conductive layer within the at least one opening; and forming a second conductive layer over the fill layer.

A method of forming a semiconductor structure in accordance with various embodiments may include: forming at least one opening in a workpiece; depositing a first conductive layer over the workpiece to line at least one of a bottom surface and one or more sidewalls of the at least one opening with the first conductive layer; filling the at least one opening with a fill layer, wherein a top surface of the fill layer is at least substantially flush with a top surface of a part of the first conductive layer outside the at least one opening; and forming a second conductive layer over the fill layer.

A method of forming a semiconductor structure in accordance with various embodiments may include: forming at least one opening in a workpiece; depositing a first conductive layer over the workpiece to partially fill the at least one opening; depositing a fill layer over the workpiece to completely fill the at least one opening; recessing the fill layer to expose a top surface of a part of the first conductive layer outside the at least one opening and form a recessed fill layer inside the at least one opening, wherein a top surface of the recessed fill layer inside the at least one opening is at least substantially flush with the top surface of the part of the first conductive layer outside the at least one opening; and depositing a second conductive layer over the top surface of the recessed fill layer and the top surface of the exposed first conductive layer.

A semiconductor structure in accordance with various embodiments may include: a workpiece comprising at least one hole; a first conductive layer lining the at least one hole; a fill layer formed within the at least one hole, wherein a top surface of the fill layer is at least substantially flush with a top surface of the first conductive layer outside the at least one hole; and a second conductive layer formed over the fill layer.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1A to FIG. 1C illustrate a conventional method of processing a semiconductor substrate including at least one opening.

FIG. 2 to FIG. 4 show various methods for forming a semiconductor structure according to various embodiments.

FIG. 5A to FIG. 5J show various views illustrating a method for forming a semiconductor structure according to various embodiments.

FIG. 6A to FIG. 6F show various views illustrating a method for forming a semiconductor structure according to various embodiments.

FIGS. 7A and 7B show cross-sectional views of semiconductor structures in accordance with various embodiments.

### DESCRIPTION

The following detailed description refers to the accompanying drawings that show, by way of illustration, specific details and embodiments in which the invention may be practised. These embodiments are described in sufficient detail to enable those skilled in the art to practice the invention. Other embodiments may be utilized and structural, logical, and electrical changes may be made without departing from the scope of the invention. The various embodiments are not necessarily mutually exclusive, as some embodiments can be combined with one or more other embodiments to form new embodiments. Various embodiments are described for structures or devices, and various embodiments are described for methods. It may be understood that one or more (e.g. all) embodiments described in connection with structures or devices may be equally applicable to the methods, and vice versa.

The word “exemplary” is used herein to mean “serving as an example, instance, or illustration”. Any embodiment or design described herein as “exemplary” is not necessarily to be construed as preferred or advantageous over other embodiments or designs.

The word “over”, used herein to describe forming a feature, e.g. a layer “over” a side or surface, may be used to mean that the feature, e.g. the layer, may be formed “directly on”, e.g. in direct contact with, the implied side or surface. The word “over”, used herein to describe forming a feature, e.g. a layer “over” a side or surface, may be used to mean that the feature, e.g. the layer, may be formed “indirectly on” the implied side or surface with one or more additional layers being arranged between the implied side or surface and the formed layer.

In like manner, the word “cover”, used herein to describe a feature disposed over another, e.g. a layer “covering” a side or surface, may be used to mean that the feature, e.g. the layer, may be disposed over, and in direct contact with, the implied side or surface. The word “cover”, used herein to describe a feature disposed over another, e.g. a layer “covering” a side or surface, may be used to mean that the feature, e.g. the layer, may be disposed over, and in indirect contact with, the implied side or surface with one or more additional layers being arranged between the implied side or surface and the covering layer.

Fabrication of modern semiconductor devices such as, e.g., integrated circuits or chips, may include forming conductive interconnects. This may sometimes include processing structures with high topography, e.g. openings, e.g. deepenings, trenches or holes having steep sidewalls. Processing of such structures with high topography (e.g. steep sidewalls) may be challenging. For example, it may be difficult to etch a dielectric layer within those structures without leaving residues.

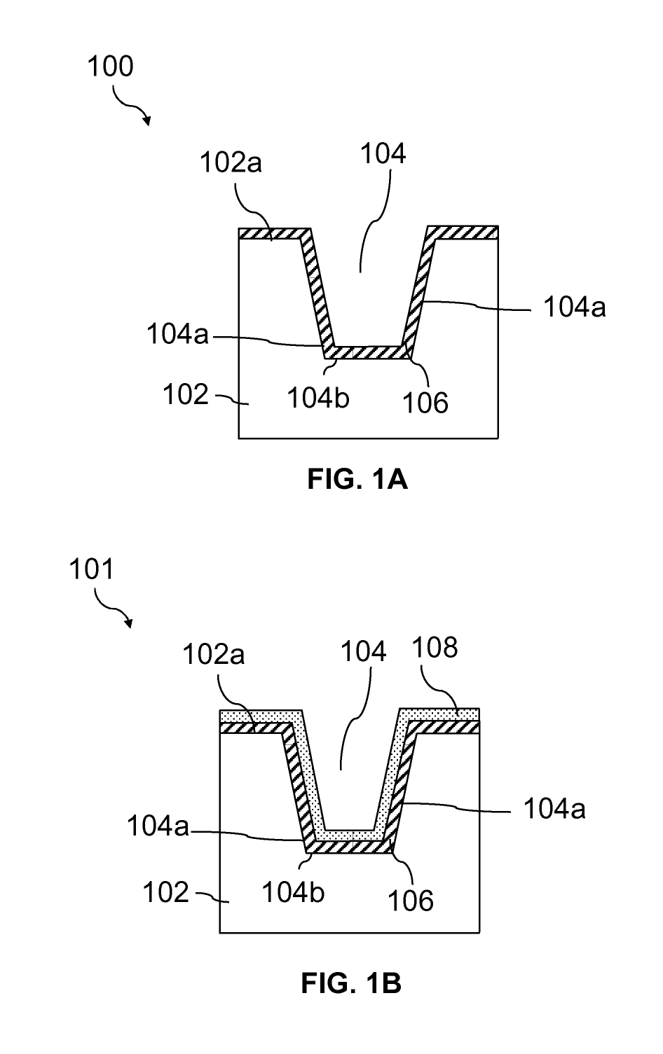

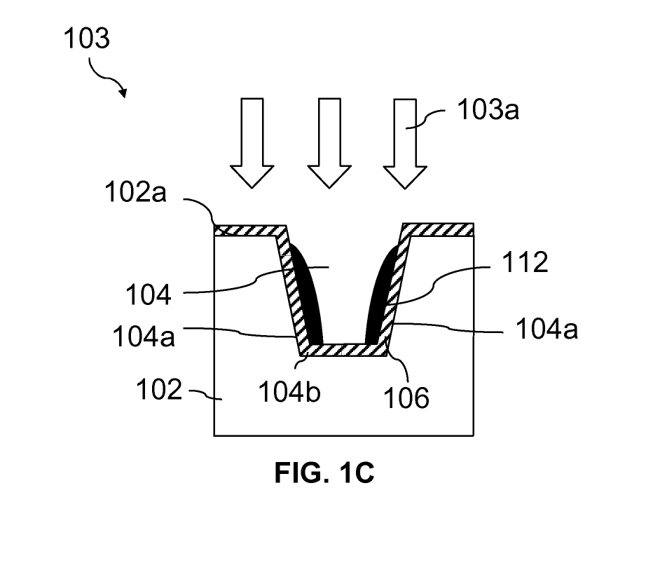

FIG. 1A to FIG. 1C illustrate a conventional method of processing a semiconductor substrate including at least one opening.

As shown in FIG. 1A in a view 100, a semiconductor substrate 102 may include one or more openings 104 (e.g. deepenings, holes or trenches) lined with a metal layer 106, for example an aluminium layer. Only one opening 104 is shown in FIG. 1A to FIG. 1C, however it may be understood that semiconductor substrate 102 may include a plurality of openings, which may, for example, all be configured in a similar or identical manner as the opening 104 shown in FIG. 1A. The opening 104 may include one or more sidewalls 104a and a bottom surface 104b.

In many cases, it may be desired to form a dielectric layer (e.g. an oxide layer) over the semiconductor substrate 102 including the one or more openings 104 and subsequently pattern the dielectric layer, e.g. by means of etching. Patterning the dielectric layer may include etching a part of the dielectric layer formed over the metal layer 106 within the opening(s) 104, as illustrated in FIG. 1B to FIG. 1C.

As shown in FIG. 1B in a view 101, a dielectric layer 108 may be deposited over the semiconductor substrate 102. The dielectric layer 108 may be disposed conformally over the surface 102a of the semiconductor substrate 102 and over the metal layer 106 within the one or more openings 104.

As shown in FIG. 1C in a view 103, the dielectric layer 108 may be etched (indicated by arrows 103a) using a conventional etching process, for example, a plasma etching process. The etching process may not completely etch a part of the dielectric layer 108 formed within the one or more openings 104. For example, a part of the dielectric layer 108 formed over the sidewalls 104a of the one or more openings 104 may have a larger vertical thickness than a part of the dielectric layer 108 formed over the bottom surface 104b of the one or more openings 104. Therefore, a conventional etching process may remove a part of the dielectric layer formed over the bottom surface 104b of the one or more openings 104 to expose a part of the metal layer 106 formed over the bottom suface 104b of the one or more openings 104, but a part of the dielectric layer 108 formed over the sidewalls 104a of the one or more openings 104 may remain.

In addition, a reaction between metal (e.g. aluminium) of the exposed part of the metal layer 106 formed over the bottom surface 104b of the one or more openings 104 and an etchant used in the etching process (e.g. a plasma, for example, a plasma containing fluorine and/or chlorine) may result in a by-product material including, or consisting of, e.g. organic polymer components and inorganic residues (e.g. aluminium oxi-fluorides). The by-product material may be resputtered over at least one sidewall 104a of the one or more openings 104 to form a protective layer over the unremoved part of the dielectric layer 108 formed over the sidewalls 104a of the one or more openings 104. The protective layer, along with the unremoved part of the dielectric layer 108 may form a residue 112 on at least one sidewall 104a of the one or more openings 104. Continued application of the etching process (indicated by arrows 103a) may not be able to remove the residue 112 from a part of the sidewalls 104a and/or a part of the bottom surface 104b of the one or more openings 104.

The residue 112 may be undesirable. For example, the residue 112 may cause corrosion of the metal layer 106. The residue 112 may limit the subsequent processing of the semiconductor substrate 102. For example, a subsequent deposition of material (e.g. plating of another metal) on the metal layer 106 having the residue 112 may cause adhesion problems between the subsequently deposited material and the metal layer 106. Therefore, delamination of the subsequently deposited material from the metal layer 106 may result. In addition, the stability and reliability of a semiconductor device formed from the semiconductor substrate 102 may be adversely affected by the residue 112.

In one or more embodiments, a fill layer may be formed over a conductive layer within an opening (e.g. deepening, hole or trench) to level or planarize a surface of a workpiece (e.g. a substrate, e.g. semiconductor substrate, e.g. wafer or chip) before further processing the workpiece, e.g. before forming a second conductive layer (e.g. a metal layer) and a dielectric layer over the workpiece and etching the dielectric layer. In one or more embodiments, the fill layer may compensate for high topography.

An effect of one or more embodiments may be a conductive layer that is at least substantially free from residues.

An effect of one or more embodiments may be a conductive layer that is at least substantially flat.

An effect of one or more embodiments may be a semiconductor structure including at least one opening, wherein a conductive layer may have a residue-free surface.

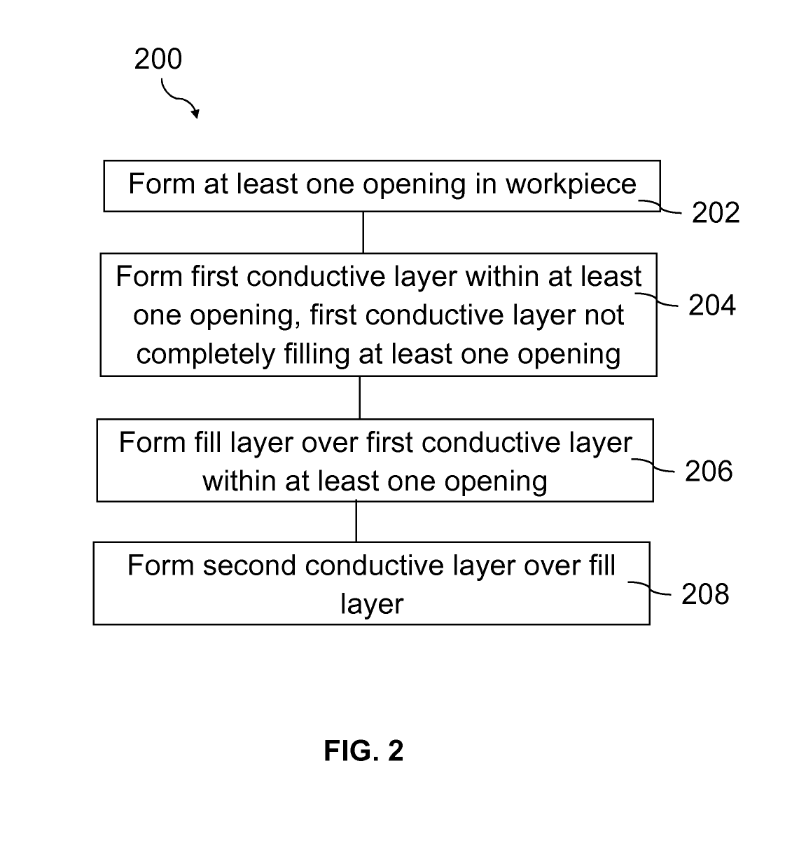

FIG. 2 to FIG. 4 show various methods for forming a semiconductor structure according to various embodiments.

In one or more embodiments, the methods for forming a semiconductor structure may be used to manufacture a semiconductor structure having one or more conductive interconnects and/or openings and/or vias.

As shown in FIG. 2, a method 200 for forming a semiconductor structure may include: forming at least one opening in a workpiece (in 202); forming a first conductive layer within the at least one opening, the first conductive layer not completely filling the at least one opening (in 204); forming a fill layer over the first conductive layer within the at least one opening (in 206); and forming a second conductive layer over the fill layer (in 208).

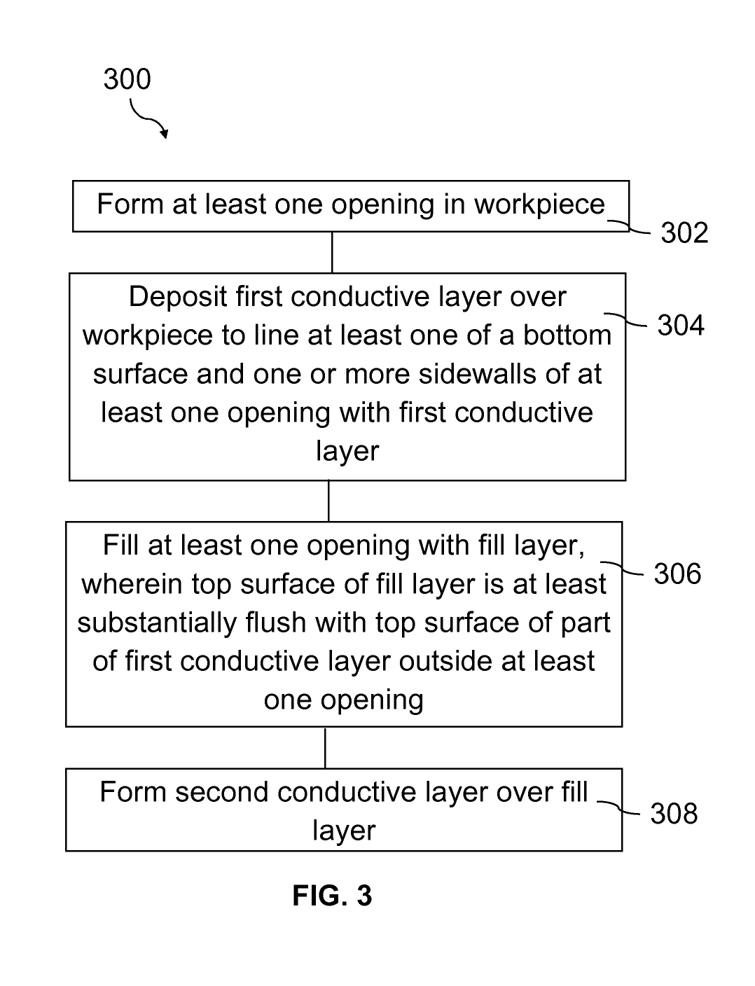

As shown in FIG. 3, a method 300 for forming a semiconductor structure may include: forming at least one opening in a workpiece (in 302); depositing a first conductive layer over the workpiece to line at least one of a bottom surface and one or more sidewalls of the at least one opening with the first conductive layer (in 304); filling the at least one opening with a fill layer, wherein a top surface of the fill layer is at least substantially flush with a top surface of a part of the first conductive layer outside the at least one opening (in 306); and forming a second conductive layer over the fill layer (in 308).

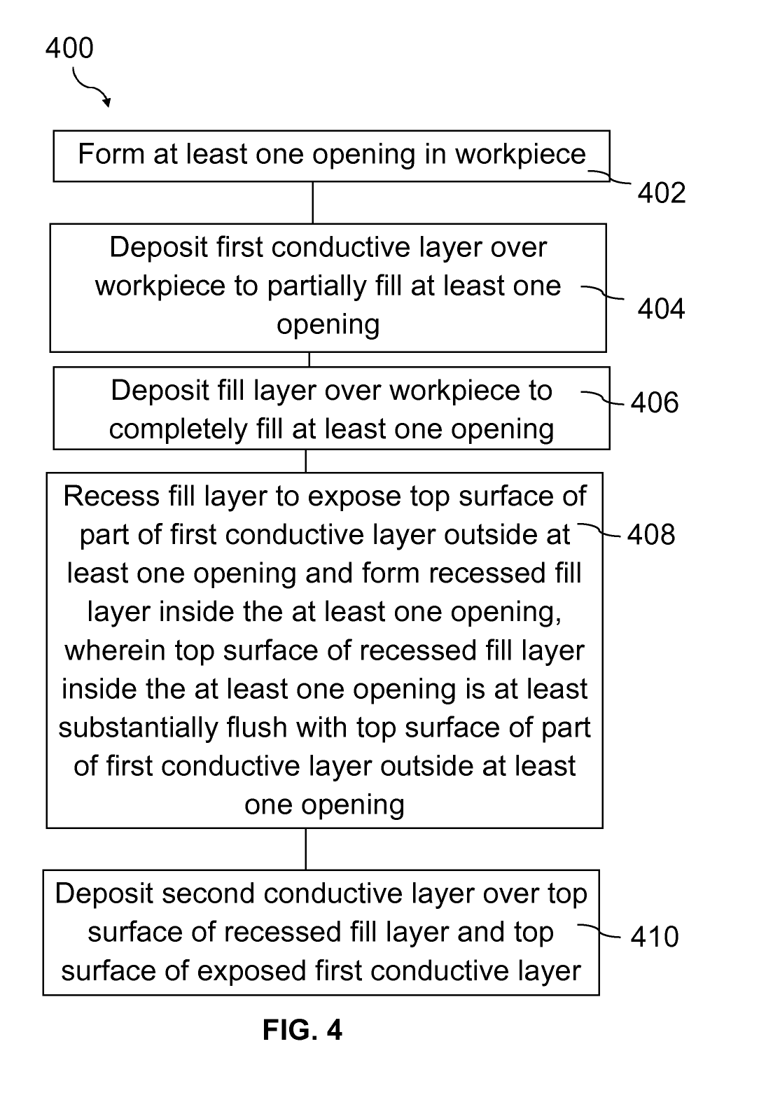

As shown in FIG. 4, a method 400 for forming a semiconductor structure may include: forming at least one opening in a workpiece (in 402); depositing a first conductive layer over the workpiece to partially fill the at least one opening (in 404); depositing a fill layer over the workpiece to completely fill the at least one opening (in 406); recessing the fill layer to expose a top surface of a part of the first conductive layer outside the at least one opening and form a recessed fill layer inside the at least one opening, wherein a top surface of the recessed fill layer inside the at least one opening is at least substantially flush with the top surface of the part of the first conductive layer outside the at least one opening (in 408); and depositing a second conductive layer over the top surface of the recessed fill layer and the top surface of the exposed first conductive layer (in 410).

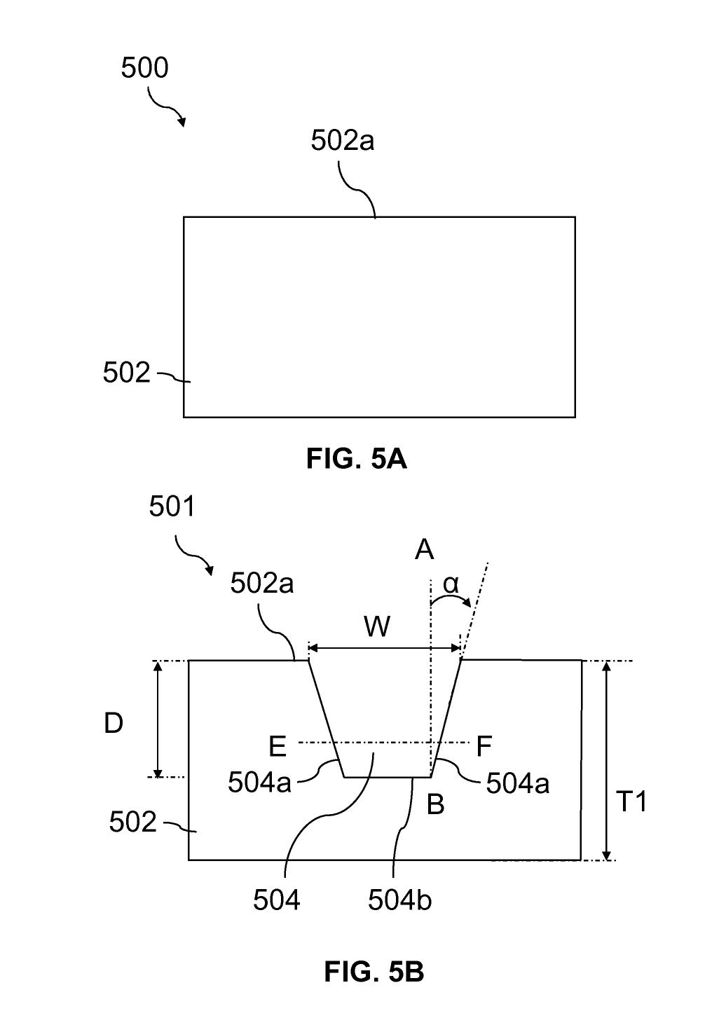

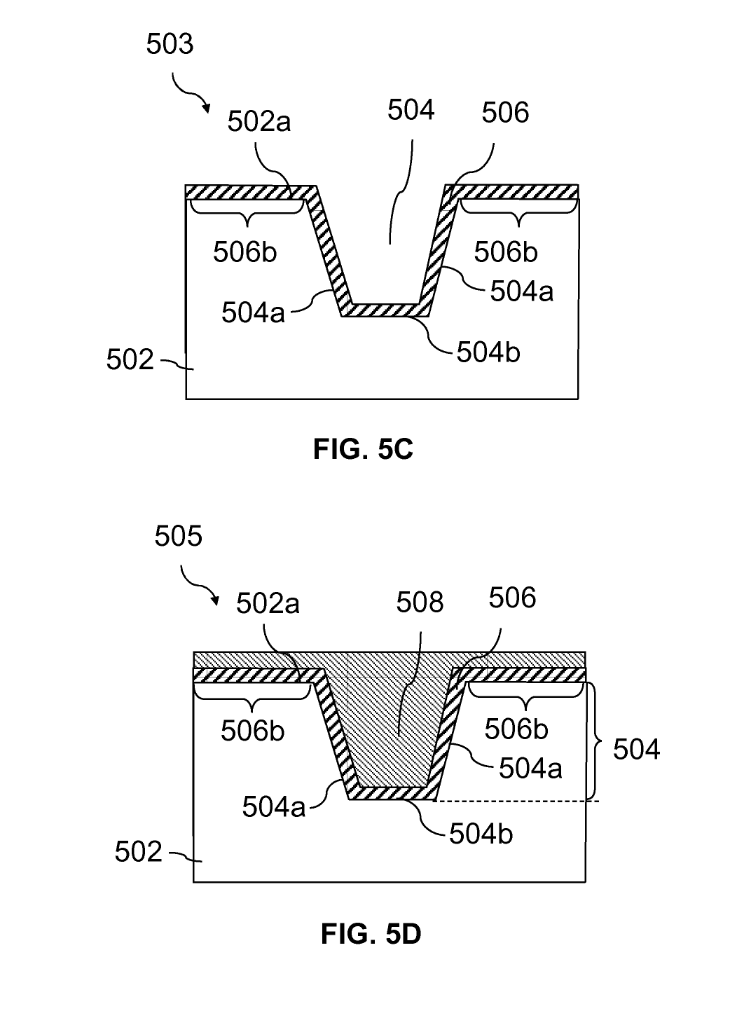

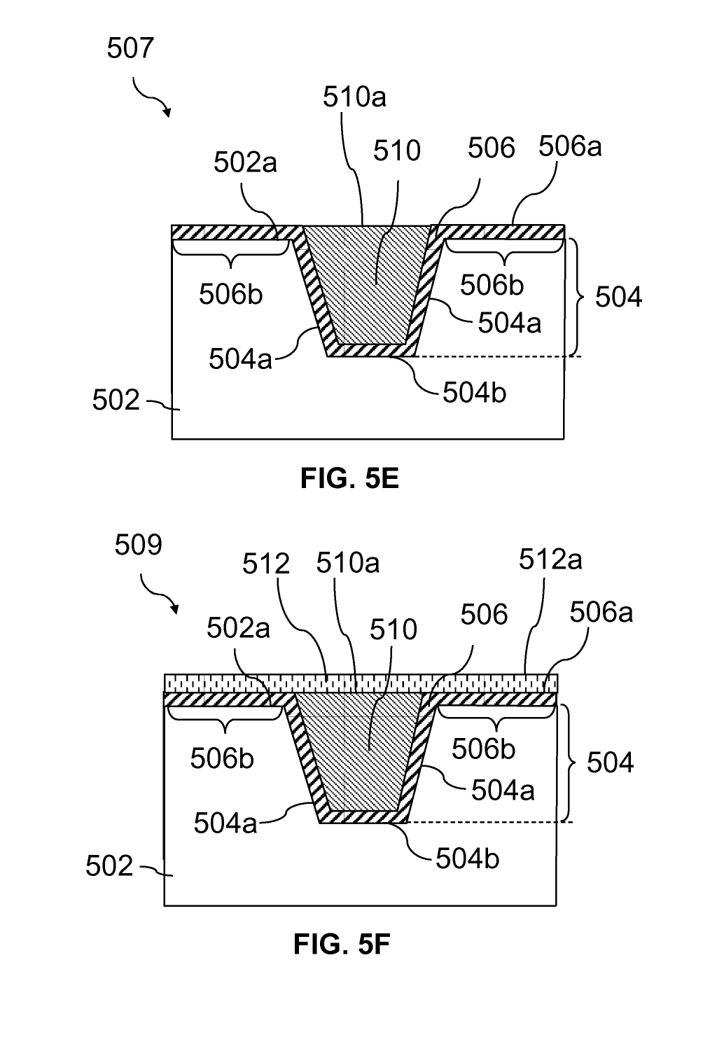

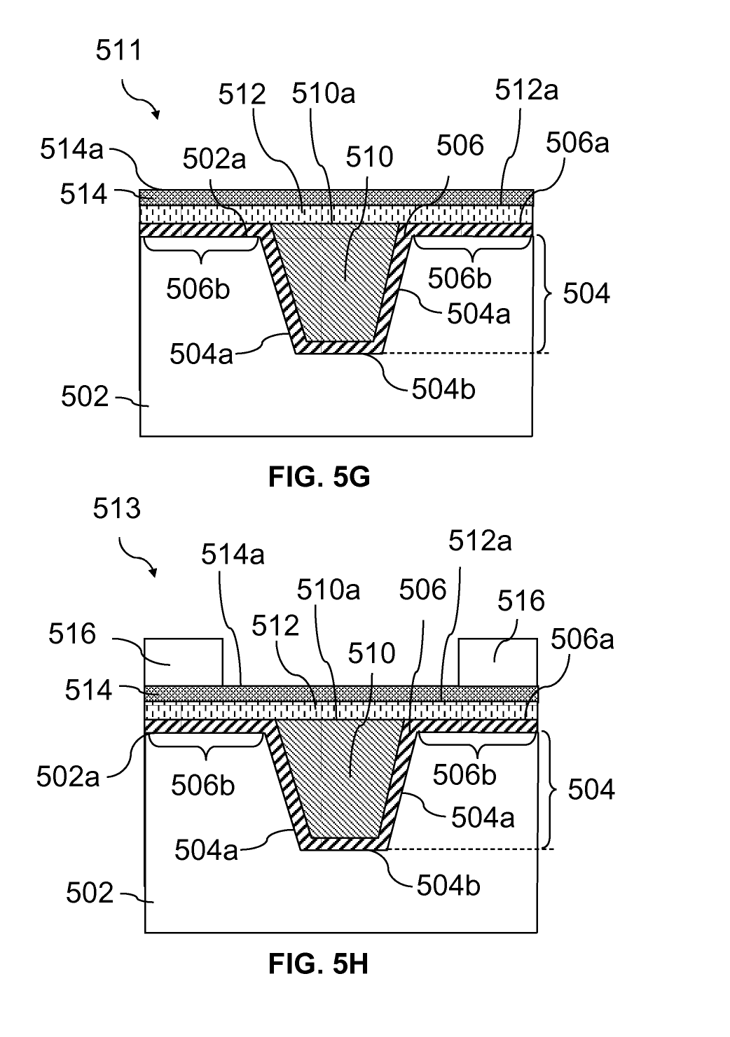

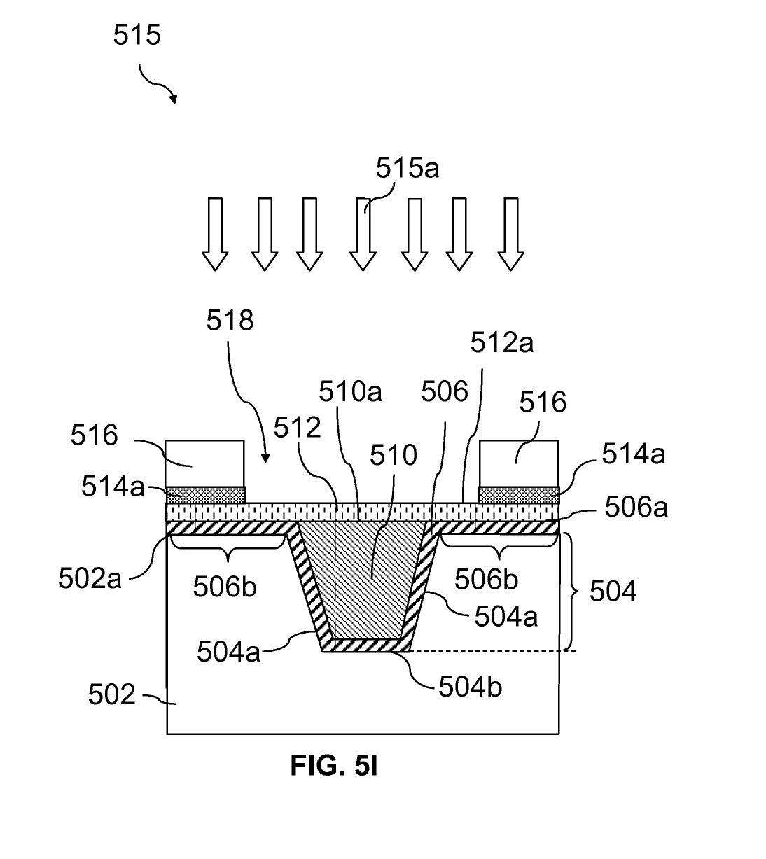

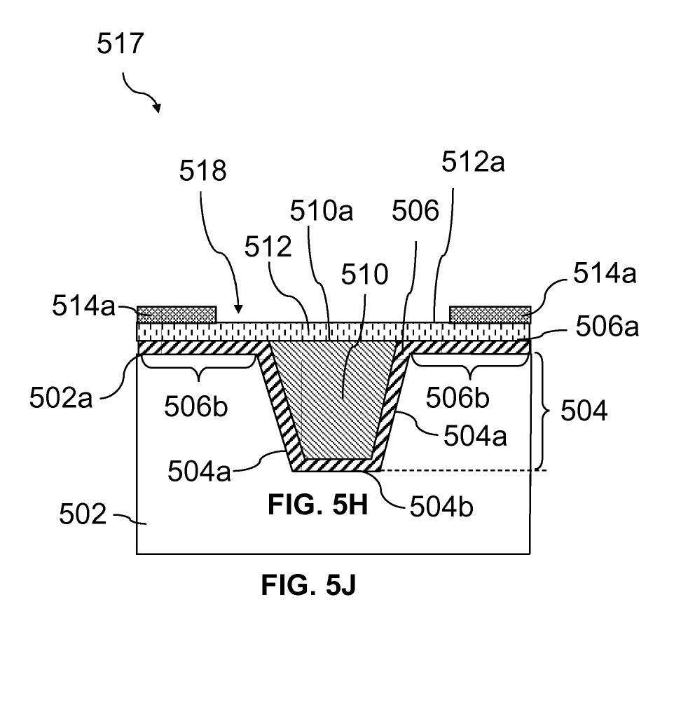

FIG. 5A to FIG. 5J show various views illustrating a method for forming a semiconductor structure according to various embodiments.

FIG. 5A shows a cross-sectional view 500 of a workpiece 502.

In one or more embodiments, the workpiece 502 may include a top surface 502a. In one or more embodiments, the top surface 502a may refer to a surface of the workpiece 502 that may be processed (e.g. by etching, by depositing material, etc.).

In one or more embodiments, the workpiece 502 may include, or may consist of, a semiconductor material such as, for example, silicon, although other semiconductor materials, including compound semiconductor materials, may be possible as well. In accordance with an embodiment, the semiconductor material may be selected from a group of materials, the group consisting of: silicon, germanium, gallium nitride, gallium arsenide, and silicon carbide, although other materials may be possible as well in accordance with other embodiments.

In one or more embodiments, the workpiece 502 may be a doped substrate, for example, a doped semiconductor substrate, such as, for example, a doped silicon substrate, a doped germanium substrate, a doped gallium nitride substrate, a doped gallium arsenide substrate, or a doped silicon carbide substrate, although other doped substrates may be possible as well in accordance with other embodiments.

In this connection, the term “doped substrate” may include a case where the entire workpiece 502 is doped, as well as a case where only a part (for example, an upper part) of the workpiece 502 is doped. The workpiece 502 may be a p-doped substrate (in other words, a workpiece 502 doped with a p-type dopant) or an n-doped substrate (in other words, a workpiece 502 doped with an n-type dopant). In accordance with an embodiment, the dopants for doping the workpiece 502 may include, or may consist of, at least one material selected from a group of materials, the group consisting of: boron, aluminium, gallium, indium, antimony, phosphorus, arsenic, and antimony, although other materials may be possible as well in accordance with other embodiments. By way of an example, the workpiece 502 may be a silicon substrate doped with a p-type dopant such as boron. By way of another example, the workpiece 502 may be a silicon substrate doped with an n-type dopant such as phosphorous, arsenic or antimony.

In one or more embodiments, the workpiece 502 may include, or may be, a bulk semiconductor substrate.

In one or more embodiments, the workpiece 502 may include, or may consist of, a substrate with at least one semiconductor layer such as, for example, a silicon-on-insulator (SOI) semiconductor substrate. In accordance with an embodiment, the at least one semiconductor layer may include, or may consist of, at least one material selected from a group of materials, the group consisting of: silicon, germanium, gallium nitride, gallium arsenide, and silicon carbide, although other materials may be possible as well in accordance with other embodiments.

In one or more embodiments, the workpiece 502 may include, or may consist of, a dielectric material. In accordance with an embodiment, the dielectric material may include at least one material selected from a group of materials, the group consisting of: an oxide, a nitride and an oxynitride, although other materials may be possible as well in accordance with other embodiments. For example, the workpiece 502 may include, or may consist of, silicon dioxide (SiO₂) and/or silicon nitride (Si₃N₄).

In one or more embodiments, the workpiece 502 may include, or may consist of, a substrate with at least one dielectric layer such as, for example, a silicon-on-insulator (SOI) semiconductor substrate. In accordance with an embodiment, the at least one dielectric layer may include at least one material selected from a group of materials, the group consisting of: an oxide, a nitride and an oxynitride, although other materials may be possible as well in accordance with other embodiments.

As shown in FIG. 5B in a view 501, at least one opening 504 may be formed in the workpiece 502.

In one or more embodiments, the at least one opening 504 formed in the workpiece 502 may include at least one of a hole (e.g. a contact hole), a via (e.g. a through-substrate hole, e.g. through-silicon via (TSV)), a deepening, and a trench, although other types of openings may be possible as well in accordance with other embodiments.

In one or more embodiments, the at least one opening 504 may extend partially through the workpiece 502. In other words, a depth D of the at least one opening 504 may be less than a thickness T1 of the workpiece 502. In one or more embodiments, the at least one opening 504 may extend through the thickness T1 of the workpiece 502, for example, when the at least one opening 504 may be a via (e.g. a through-substrate hole, e.g. through-silicon via (TSV)).

In accordance with an embodiment, the depth D of the at least one opening 504 may be in the range from about 100 nm to about 500 μm, for example in the range from about 500 nm to about 100 μm, for example in the range from about 1 μm to about 100 μm, in the range from about 3 μm to about 100 μm, for example in the range from about 3 μm to about 80 μm, for example in the range from about 3 μm to about 50 μm, for example in the range from about 3 μm to about 25 μm, for example in the range from about 3 μm to about 15 μm, for example in the range from about 3 μm to about 8 μm, for example about 4 μm, although other values may be possible as well in accordance with other embodiments.

In one or more embodiments, the at least one opening 504 may include at least one sidewall 504a and a bottom surface 504b. In accordance with an embodiment, the at least one sidewall 504a of the at least one opening 504 may be slanted. In accordance with an embodiment, an angle α subtended by the at least one sidewall 504a and a line perpendicular to the top surface 502a of the workpiece 502 (e.g. the line A-B in FIG. 5B) may be less than or equal to about 45°, for example less than or equal to about 35°, for example less than or equal to about 30°, for example less than or equal to about 25°, for example less than or equal to about 20°, for example less than or equal to about 15°, for example less than or equal to about 10°, for example less than or equal to about 5°, although other values may be possible as well in accordance with other embodiments.

In accordance with an embodiment, the width W of the at least one opening 504 may be measured as the widest lateral extent of the at least one opening 504. For example, the width W may be measured as the lateral extent of the at least one opening 504 at the top surface 502a of the workpiece 502. In one or more embodiments, the width W of the at least one opening 504 may be in the range from about 100 nm to about 100 μm, for example in the range from about 500 nm to about 100 μm, for example in the range from about 1 μm to about 100 μm, for example in the range from about 5 μm to about 100 μm, for example in the range from about 10 μm to about 100 μm, for example in the range from about 15 μm to about 100 μm, for example in the range from about 30 μm to about 100 μm, for example in the range from about 40 μm to about 100 μm, for example in the range from about 60 μm to about 100 μm, for example in the range from about 80 μm to about 100 μm, for example about 100 μm, although other values may be possible as well in accordance with other embodiments.

An aspect ratio of an opening of the at least one opening 504 may be calculated as a ratio of the depth D to the width W of the opening, in other words D:W. In accordance with an embodiment, the aspect ratio (D:W) of the at least one opening 504 may be less than or equal to about 1, for example less than or equal to about 0.5, for example less than or equal to about 0.2. In accordance with another embodiment, the aspect ratio (D:W) of the at least one opening 504 may be greater than or equal to about 1, for example greater than or equal to about 2, for example greater than or equal to about 5, for example greater than or equal to about 10, for example, greater than or equal to about 25, although other values may be possible as well in accordance with other embodiments.

In accordance with an embodiment, a cross-section of the at least one opening 504 along a plane E-F shown in FIG. 5B may, for example, have a circular shape, a rectangular shape, a triangular shape, an oval shape, a quadratic shape, a polygonal shape, or an irregular shape, although other shapes may be possible as well in accordance with other embodiments.

In one or more embodiments, the at least one opening 504 in the workpiece 502 may be formed by means of an etching process. In one or more embodiments, the etching process may include, or may be, at least one of a wet etch process and a dry etch process (e.g. a plasma etch process, for example, a Bosch etch process), or other suitable etching processes, which may be known as such in the art.

In accordance with an embodiment, the etching process may be performed in conjunction with a patterned etch mask, which may be formed over a part of the top surface 502a of the workpiece 502. In accordance with an embodiment, the patterned etch mask may be formed by depositing a masking material over the workpiece 502, and patterning the masking material to form the patterned etch mask. In one or more embodiments, patterning the masking material may include, or may consist of, a lithographic process (e.g. a photo-lithographic process.) In one or more embodiments, the patterned etch mask may be removed after forming the at least one opening 504.

In one or more embodiments, the at least one opening 504 in the workpiece 502 may be formed by means of a process other than an etching process, for example by means of a structured deposition process, or by means of depositing a light-sensitive material (e.g. photo-imide), exposure of the light-sensitive material and development of the exposed light-sensitive material, or by means of other suitable processes.

As shown in FIG. 5C in a view 503, a first conductive layer 506 may be formed within the at least one opening 504.

In one or more embodiments, the first conductive layer 506 formed within the at least one opening 504 may be formed over the at least one sidewall 504a and/or bottom surface 504b of the at least one opening 504. In one or more embodiments, the first conductive layer 506 may coat the at least one sidewall 504a and/or the bottom surface 504b of the at least one opening 504. In one or more embodiments, the first conductive layer 506 formed within the at least one opening 504 may line the one or more sidewalls 504a and/or the bottom surface 504b of the at least one opening 504. In one or more embodiments, the first conductive layer 506 formed within the at least one opening 504 may clad the one or more sidewalls 504a and/or the bottom surface 504b of the at least one opening 504. In one or more embodiments, the first conductive layer 506 may partially fill the at least one opening 504. Stated differently, in one or more embodiments, the first conductive layer 506 may fill only part of the at least one opening 504 but may not completely fill the at least one opening 504.

In one or more embodiments, forming the first conductive layer 506 within the at least one opening 504 may include forming the first conductive layer 506 over at least one sidewall 504a and/or a bottom surface 504b of the at least one opening 504, and over a part of the top surface 502a of the workpiece 502 (as shown in FIG. 5C). Therefore, in one or more embodiments, a part 506b of the first conductive layer 506 may lie outside the at least one opening 504. In one or more embodiments, the part 506b of the first conductive layer 506 outside the at least one opening 504 may be disposed over a part of the top surface 502a of the workpiece 502.

In one or more embodiments, the first conductive layer 506 may be formed within the at least one opening 504 by means of a deposition process, for example a conformal deposition process, for example, at least one of an atomic layer deposition (ALD) process, a plating process, a chemical vapor deposition (CVD) process, a low-pressure CVD (LPCVD) process, a plasma-enhanced chemical vapor deposition (PECVD) process, a high-density plasma chemical vapor deposition (HDP-CVD) process, a physical vapor deposition (PVD) process, an electrochemical deposition process, and a sputtering process, or other suitable deposition processes, which may be known as such in the art.

In one or more embodiments, the first conductive layer 506 may be formed within the at least one opening 504 by means of a growth process, such as, for example, an epitaxial growth process, or other suitable growth processes, which may be known as such in the art.

In one or more embodiments, the deposition and/or growth process may be performed in conjunction with a patterned deposition mask disposed over a part of the top surface 502a of the workpiece 502. The patterned deposition mask may be removed from the workpiece 502 after forming the first conductive layer 506.

In one or more embodiments, the first conductive layer 506 may include, or may consist of, a metal or metal alloy. In one or more embodiments, the metal may include at least one metal selected from a group of metals, the group consisting of: copper, aluminium, and gold, or an alloy containing at least one of the aforementioned metals. In one or more embodiments, the first conductive layer 506 may include, or may consist of, a material containing one or more of the aforementioned metals and in addition a small amount (e.g. single digit percentage amount) of silicon, e.g. AlSiCu (e.g. containing between 0.5 wt. % and 2 wt. % of Si, and 0.5 wt. % and 2 wt. % of Cu).

In one or more embodiments, the first conductive layer 506 may have a thickness in the range from about 100 nm to about 10 μm, for example in the range from about 200 nm to about 10 μm, for example in the range from about 500 nm to about 10 μm, for example, in the range from about 500 nm to about 8 μm, for example, in the range from about 1 μm to about 8 μm, for example, in the range from about 3 μm to about 6 μm, for example about 5 μm, although other values may be possible as well in accordance with other embodiments.

In one or more embodiments, a plurality of openings 504 may be formed in the workpiece 502. Only one opening 504 is shown as an example, however the number of openings 504 may be greater than one, and may, for example, be on the order of tens, hundreds of, or even more, openings in some embodiments. In one or more embodiments, the first conductive layer 506 may be formed within the plurality of openings 504. In one or more embodiments, the first conductive layer 506 formed within at least one opening of the plurality of openings 504 may be physically and/or electrically isolated from the first conductive layer 506 formed within at least one other opening of the plurality of openings 504. In one or more embodiments, the first conductive layer 506 formed within at least one opening of the plurality of openings 504 may be connected (e.g. physically and/or electrically connected) to the first conductive layer 506 formed within at least one other opening of the plurality of openings 504.

As shown in FIG. 5D in a view 505, a fill layer 508 may be formed (e.g. deposited) over the workpiece 502.

In one or more embodiments, the fill layer 508 may be deposited into the at least one opening 504. In one or more embodiments, the fill layer 508 may completely fill the at least one opening 504. In one or more embodiments, the fill layer 508 may be formed (e.g. deposited) over the part 506b of the first conductive layer 506 outside the at least one opening 504 (as shown in FIG. 5D).

In one or more embodiments, the fill layer 508 may be deposited over the workpiece 502 by means of a deposition process such as, for example, at least one of a chemical vapor deposition (CVD) process, a low-pressure CVD (LPCVD) process, a plasma-enhanced chemical vapor deposition (PECVD) process, a high-density plasma chemical vapor deposition (HDP-CVD) process, a physical vapor deposition (PVD) process, a sputtering process, and a spin coating process, or other suitable deposition processes, which may be known as such in the art.

In one or more embodiments, the deposition process may be performed in conjunction with a patterned deposition mask disposed over a part of the top surface 502a of the workpiece 502. The patterned deposition mask may be removed from the workpiece after forming the fill layer 508. In one or more embodiments, the patterned deposition mask used in forming the first conductive layer 506 may additionally be used as the patterned deposition mask in forming the fill layer 508.

In one or more embodiments, the fill layer 508 may include, or may consist of, a material and/or compound that may be recessed, for example by means of etching. In one or more embodiments, the fill layer 508 may include, or may consist of, a material that may be leveled or eroded.

In one or more embodiments, the fill layer 508 may serve to planarize (in other words, level) a surface profile of the first conductive layer 506. For example, the fill layer 508 may serve to compensate a height difference between the surface of the first conductive layer 506 within the at least one opening 504 and a surface of the first conductive layer 506 outside the at least one opening 504. Accordingly, in one or more embodiments, the fill layer 508 may also be referred to as a planarization layer, and/or the material of the fill layer 508 may also be referred to as a planarization material.

In one or more embodiments, the fill layer 508 may include, or may consist of at least one material selected from a group of materials, the group consisting of: a resist material, an imide material, and benzocyclobutene (BCB), although other materials may be possible as well in accordance with other embodiments.

In one or more embodiments, the fill layer 508 may include, or may consist of, at least one material selected from a group of materials, the group consisting of: an epoxy, an acrylic resin, a vinyl, and an organometal, although other materials may be possible as well in accordance with other embodiments.

In one or more embodiments, the fill layer 508 may include, or may consist of, a dielectric material. In one or more embodiments, the dielectric material may include, or may consist of, at least one material selected from a group of materials, the group consisting of: an oxide material, a nitride material, and an oxynitride material, although other materials may be possible as well in accordance with other embodiments.

In one or more embodiments, the fill layer 508 may include, or may consist of, a conductive material, such as, for example solder paste, copper, tungsten, titanium, titanium nitride, although other conductive materials may be possible as well in accordance with other embodiments.

As shown in FIG. 5E in a view 507, the fill layer 508 may be recessed to form a recessed fill layer 510.

In one or more embodiments, the fill layer 508 may be recessed using a recessing process, for example at least one of an etching process (e.g. a plasma etch process) and a chemical-mechanical polishing process (CMP), or other suitable recessing processes, which may be known as such in the art.

In one or more embodiments, the recessing process may be performed until a top surface 506a of the part 506b of the first conductive layer 506 outside the at least one opening 504 is exposed. Accordingly, in accordance with an embodiment, recessing the fill layer 508 may include recessing the fill layer 508 to expose the top surface 506a of the part 506b of the first conductive layer 506 outside the at least one opening 504.

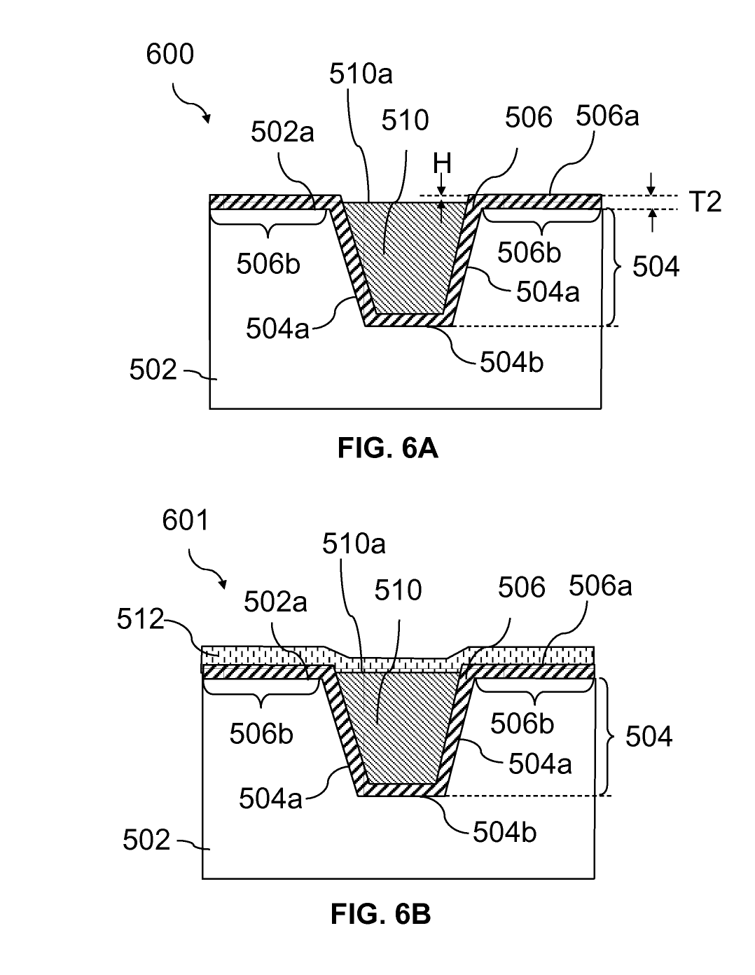

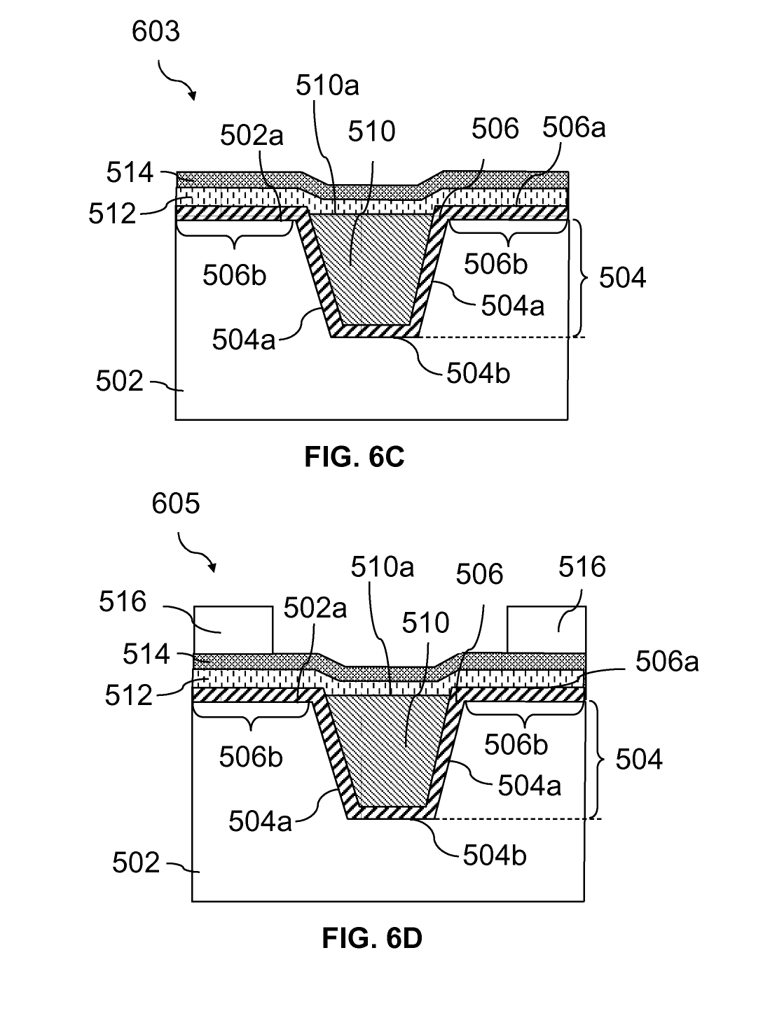

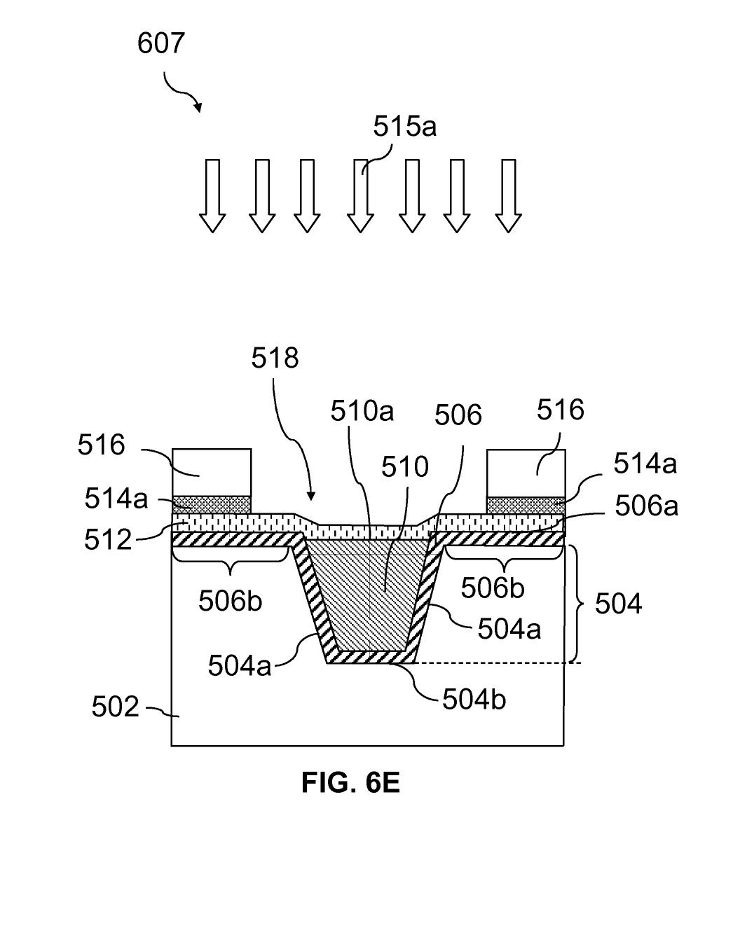

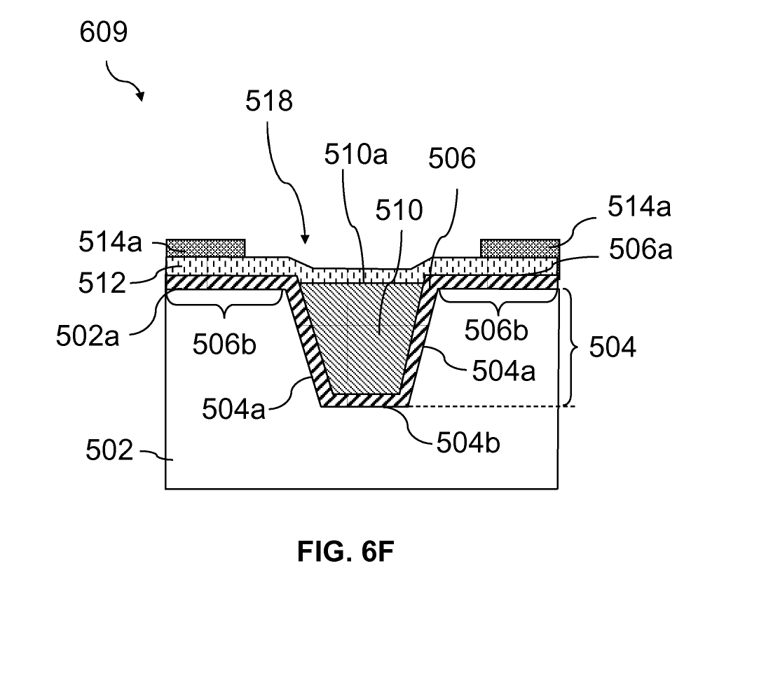

In one or more embodiments, a top surface 510a of the recessed fill layer 510 may be flush with the top surface 506a of the part 506b of the first conductive layer 506 outside the at least one opening 504. For example, the top surface 506a and the top surface 510a may form a planar or flat surface. For example, in one or more embodiments, a height difference between the top surface 510a of the recessed fill layer 510 and the top surface 506a of the part 506b of the first conductive layer 506 outside the at least one opening 504 may be zero or substantially zero. In other embodiments, the top surface 510a may be substantially flush with the top surface 506a of the part 506b of the first conductive layer 506 outside the at least one opening 504, as described herein below in connection with FIG. 6A.

As shown in FIG. 5F in a view 509, a second conductive layer 512 may be formed over the recessed fill layer 510.

In one or more embodiments, the second conductive layer 512 may also be formed over at least part of the top surface 506a of the part 506b of the first conductive layer 506 outside the at least one opening 504 (as shown in FIG. 5F).

In one or more embodiments, the second conductive layer 512 may be formed by means of a deposition process. For example, in one or more embodiments, the second conductive layer 512 may be deposited over the top surface 510a of the recessed fill layer 510 and/or over at least part of the top surface 506a of the part 506b of the first conductive layer 506 outside the at least one opening 504.

In one or more embodiments, the deposition process may include, or may be, at least one of a plating process, a chemical vapor deposition (CVD) process, a low-pressure CVD (LPCVD) process, a plasma-enhanced chemical vapor deposition (PECVD) process, a high-density plasma chemical vapor deposition (HDP-CVD) process, a physical vapor deposition (PVD) process, and a sputtering process, or other suitable deposition processes, which may be known as such in the art.

In one or more embodiments, the deposition process may be performed in conjunction with a patterned deposition mask disposed over a part of the top surface 502a of the workpiece 502. The patterned deposition mask may be removed from the workpiece 502 after forming the second conductive layer 512.

In one or more embodiments, the second conductive layer 512 may include, or may consist of, a metal or metal alloy. In one or more embodiments, the metal may include at least one metal selected from a group of metals, the group consisting of: copper, aluminium, and gold, or an alloy containing at least one of the aforementioned metals. In one or more embodiments, the second conductive layer 512 may include, or may consist of, a material containing one or more of the aforementioned metals and in addition a small amount (e.g. single digit percentage amount) of silicon, e.g. AlSiCu (e.g. containing between 0.5 wt. % and 2 wt. % of Si, and 0.5 wt. % and 2 wt. % of Cu).

In one or more embodiments, the second conductive layer 512 may have a thickness in the range from about 100 nm to about 30 μm, for example in the range from about 200 nm to about 20 μm, for example in the range from about 500 nm to about 10 μm, for example, in the range from about 500 nm to about 8 μm, for example, in the range from about 1 μm to about 8 μm, for example, in the range from about 3 μm to about 6 μm, for example about 5 μm, although other values may be possible as well in accordance with other embodiments.

In accordance with an embodiment, the second conductive layer 512, e.g. a top surface 512a of the second conductive layer 512, may be substantially planar at least in a region corresponding to the opening 504. In other words, the second conductive layer 512, or the top surface 512a of the second conductive layer 512, may be substantially flat. In one or more embodiments, the substantial planarity or flatness of the second conductive layer 512 may be an effect of the top surface 510a of the recessed fill layer 510 being substantially flush with the top surface 506a of the part 506b of the first conductive layer 506 outside the at least one opening 504.

As shown in FIG. 5G in a view 511, a dielectric layer 514 may be formed over the second conductive layer 512 in one or more embodiments.

In one or more embodiments, the dielectric layer 514 may be formed over the second conductive layer 512 by depositing the dielectric layer 514 over the second conductive layer 512 by means of a deposition process. In one or more embodiments, the deposition process may include, or may be, at least one of a chemical vapor deposition (CVD) process, a low-pressure CVD (LPCVD) process, a plasma-enhanced chemical vapor deposition (PECVD) process, a high-density plasma chemical vapor deposition (HDP-CVD) process, a physical vapor deposition (PVD) process, a sputtering process, and a spin coating process, or other suitable deposition processes, which may be known as such in the art.

In one or more embodiments, the dielectric layer 514 may be formed over the top surface 512a of the second conductive layer 512. In one or more embodiments, the dielectric layer 514 may be formed over (e.g. deposited over) a part of the second conductive layer 512 (e.g. the top surface 512a of the second conductive layer 512) located above, e.g. directly above, the opening 504. In one or more embodiments, the dielectric layer 514 may be formed over a part of the second conductive layer 512 located above, e.g. directly above, the part 506b of the first conductive layer 506 outside the at least one opening 504. In one or more embodiments, the dielectrice layer 514 may be formed over at least one part of the first conductive layer 506 which is free from the second conductive layer 512. In one or more embodiments, the dielectric layer 514 may be formed over at least one part of the workpiece 502 which may be free from the first conductive layer 506 and/or the second conductive layer 512.

In accordance with an embodiment, the dielectric layer 514, e.g. an upper surface 514a of the dielectric layer 514, may be substantially planar or flat at least in a region corresponding to the opening 504. In one or more embodiments, the substantial planarity or flatness of the dielectric layer 514 may be an effect of the top surface 510a of the recessed fill layer 510 being substantially flush with the top surface 506a of the part 506b of the first conductive layer 506 outside the at least one opening 504.

In one or more embodiments, the dielectric layer 514 may include, or may consist of, at least one material selected from a group of materials, the group consisting of: an oxide, a nitride and an oxynitride, although other materials may be possible as well in accordance with other embodiments. For example, the dielectric material 514 may include, or may consist of, silicon dioxide (SiO₂), or a high-k dielectric such as tantalum oxide or hafnium oxide.

In one or more embodiments, at least one opening may be formed through the dielectric layer 514. FIG. 5H and FIG. 5I illustrate a process of forming the at least one opening through the dielectric layer 514.

As shown in FIG. 5H in a view 513, a patterned mask layer 516 may be formed over the dielectric layer 514 (e.g. over the top surface 514a of the dielectric layer 514). In one or more embodiments, the patterned mask layer 516 may be formed by depositing a masking layer over the dielectric layer 514, and patterning the masking layer to form the patterned mask layer 516. In one or more embodiments, the masking layer may be deposited by means of a suitable deposition process (e.g. a spin coating process). In one or more embodiments, patterning the masking layer to form the patterened mask layer 516 may be performed by means of a lithographic process (e.g. photo-lithographic process) or other suitable patterning processes, which may be known as such in the art.

In one or more embodiments, the patterned mask layer 516 may include, or may consist of, a resist material, such as, for example, a photoresist material, an imide material, a polyimide material, an epoxy material (such as, for example, SU-8), benzocyclobutene (BCB), although other materials may be possible as well in accordance with other embodiments.

As shown in FIG. 5I in a view 515, at least one opening 518 may be formed through the dielectric layer 514.

In one or more embodiments, the at least one opening 518 may be formed through the dielectric layer 514 by etching (indicated by arrows 515a) the dielectric layer 514 using the patterned mask layer 516 as an etch mask. In one or more embodiments, etching the dielectric layer 514 may be performed by means of an etching process (e.g. a wet etch process, or a dry etch process, for example a plasma etch process).

In one or more embodiments, the at least one opening 518 formed through the dielectric layer 514 may expose a part of the second conductive layer 512 disposed over the recessed fill layer 510. In one or more embodiments, the at least one opening 518 formed through the dielectric layer 514 may expose a part of the second conductive layer 512 disposed over the recessed fill layer 510 and a part of the second conductive layer 512 disposed over the first conductive layer 506 (as shown in FIG. 5I).

As seen in FIG. 5I, the substantial planarity of the second conductive layer 512 may result in a semiconductor structure having at least one opening 518 in a dielectric layer 514, wherein a conductive layer (e.g. the second conductive layer 512) may be free or substantially free from residues, e.g. residues of the dielectric layer 514 and/or resputtered material of the conductive layer (e.g. second conductive layer 512), after an etching process used for etching the dielectric layer 514.

As shown in FIG. 5J in a view 517, the patterned mask layer 516 may be removed after forming the at least one opening 518 through the dielectric layer 514. In one or more embodiments, a part 514a of the dielectric layer 514 remaining after forming the at least one opening 518 may be disposed over a part of the top surface 502a of the workpiece 502 which may be free from the first conductive layer 506 and/or second conductive layer 512 (not shown).

FIG. 6A to FIG. 6F show various views illustrating a method for forming a semiconductor structure according to various embodiments.

Reference signs in FIG. 6A to FIG. 6F that are the same as in FIG. 5E to FIG. 5J denote the same or similar elements as in FIG. 5E to FIG. 5J. Thus, those elements will not be described in detail again here; reference is made to the description above. Differences between FIG. 6A to FIG. 6F and FIG. 5E to FIG. 5J are described below.

As shown in FIG. 6A in a view 600, a recessed fill layer 510 may be formed over the first conductive layer 506 within the at least one opening 504, similarly as described above in connection with FIG. 5A to FIG. 5E.

As described above, the recessed fill layer 510 may be formed by recessing the fill layer 508 shown in FIG. 5D using a recessing process (e.g. an etching process and/or a chemical-mechanical polishing process (CMP)).

As described above, recessing the fill layer 508 may include recessing the fill layer 508 to expose the top surface 506a of the part 506b of the first conductive layer 506 outside the at least one opening 504.

In one or more embodiments, the top surface 510a of the recessed fill layer 510 may be below the top surface 506a of the part 506b of the first conductive layer 506 outside the at least one opening 504. In one or more embodimetnts, the top surface 510a of the recessed fill layer 510 may be substantially flush with the top surface 506a of the part 506b of the first conductive layer 506 outside the at least one opening 504. In one or more embodiments, a height difference H between the top surface 510a of the recessed fill layer 510 and the top surface 506a of the part 506b of the first conductive layer 506 outside the at least one opening 504 may be less than or equal to about half a thickness T2 of the part 506b of the first conductive layer 506 outside the at least one opening 504, which may, for example, correspond to the thickness of the first conductive layer 506 described above and may, for example, be in the range from about 500 nm to about 10 μm, although other values may be possible as well.

In one or more embodiments, the height difference H between the top surface 510a of the recessed fill layer 510 and the top surface 506a of the part 506b of the first conductive layer 506 outside the at least one opening 504 may be less than or equal to about 5 μm, for example less than or equal to about 2 μm, for example less than or equal to about 1 μm, for example less than or equal to about 800 nm, for example less than or equal to about 500 nm, for example less than or equal to about 400 nm, for example less than or equal to about 250 nm, for example less than or equal to about 100 nm, for example less than or equal to about 50 nm, for example less than or equal to about 10 nm, for example less than or equal to about 5 nm, for example less than or equal to about 2 nm, for example less than or equal to about 1 nm, although other values may be possible as well in accordance with other embodiments.

As shown in FIG. 6B in a view 601, the second conductive layer 512 may be formed over the recessed fill layer 510.

As described above, in one or more embodiments the second conductive layer 512 may be formed over the recessed fill layer 510 by means of a deposition process (e.g. a plating process, a sputtering process, etc.)

In accordance with an embodiment, the second conductive layer 512 may exhibit low topography. In other words, the second conductive layer 512 may have shallow and/or low relief. Stated differently, the second conductive layer 512 may be free from steep features, for example, steep slopes and/or sidewalls. In one or more embodiments, the shallow and/or low topography of the second conductive layer 512 may be an effect of the top surface 510a of the recessed fill layer 510 being substantially flush with the top surface 506a of the part 506b of the first conductive layer 506 outside the at least one opening 504, for example of the height difference between the top surface 510a of the recessed fill layer 510 and the top surface 506a of the part 506b of the first conductive layer 506 outside the at least one opening 504 being less than or equal to about half a thickness of the part 506b of the first conductive layer 506 outside the at least one opening 504.

As shown in FIG. 6C in a view 603, the dielectric layer 514 may be formed over the second conductive layer 512 in one or more embodiments.

In one or more embodiments, a part of the dielectric layer 514 disposed over the second conductive layer 512 may exhibit low topography (e.g. shallow and/or low relief). In one or more embodiments, the low topography of the part of the dielectric layer 514 disposed over the second conductive layer 512 may be an effect of the top surface 510a of the recessed fill layer 510 being substantially flush with the top surface 506a of the part 506b of the first conductive layer 506 outside the at least one opening 504, for example of the height difference between the top surface 510a of the recessed fill layer 510 and the top surface 506a of the part 506b of the first conductive layer 506 outside the at least one opening 504 being less than or equal to about half a thickness of the part 506b of the first conductive layer 506.

In one or more embodiments, at least one opening may be formed through the dielectric layer 514. FIG. 6D and FIG. 6E illustrate a process of forming the at least one opening through the dielectric layer 514.

As shown in FIG. 6D in a view 605, the patterned mask layer 516 may be formed over the dielectric layer 514.

As shown in FIG. 6E in a view 607, the at least one opening 518 may be formed through the dielectric layer 514.

As described above, the at least one opening 518 may be formed through the dielectric layer 514 by etching the dielectric layer 514 using the patterned mask layer 516 as an etch mask. In one or more embodiments, etching the dielectric layer 514 may be performed by means of an etching process (e.g. a wet etch process, or a dry etch process, for example a plasma etch process).

As seen in FIG. 6E, the low topography (e.g. shallow and/or low relief) of the second conductive layer 512 may result in a semiconductor structure having at least one opening 518 in a dielectric layer 514, wherein a conductive layer (e.g. second conductive layer 512) may be free or substantially free from residues, e.g. residues of the dielectric layer 514 and/or resputtered material of the conductive layer (e.g. second conductive layer 512), after an etching process used for etching the dielectric layer 514.

As shown in FIG. 6F in a view 609, the patterned mask layer 516 may be removed after forming the opening 518 through the dielectric layer 514. As described above, in one or more embodiments the part 514a of the dielectric layer 514 remaining after forming the opening 518 may be disposed over a part of the top surface 502a of the workpiece 502 which may be free from the first conductive layer 506 and/or second conductive layer 512 (not shown).

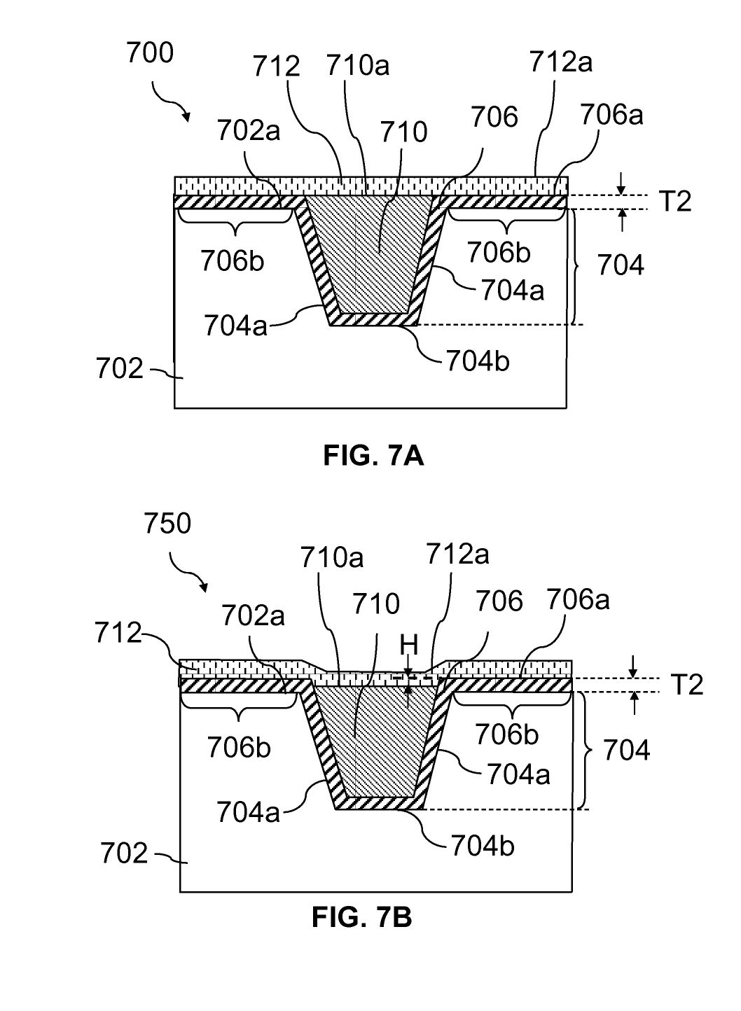

FIG. 7A and FIG. 7B show cross-sectional views of a semiconductor structure in accordance with various embodiments.

As shown in FIG. 7A, a semiconductor structure 700 may include a workpiece 702 including at least one opening 704 (e.g. a hole, a deepening, a cavity, a via, a recess, or a trench). In one or more embodiments, the semiconductor structure 700 may include a first conductive layer 706 (e.g. including a metal or metal alloy) lining the at least one opening 704. In one or more embodiments, the semiconductor structure 700 may include a fill layer 710 formed within the at least one opening 704, wherein a top surface 710a of the fill layer 710 may be flush with a top surface 706a of a part 706b of the first conductive layer 706 outside the at least one opening 704. In one or more embodiments, a height difference between the top surface 710a of the fill layer 710 and the top surface 706a of the part 706b of the first conductive layer 706 outside the at least one opening 704 may be zero or substantially zero. In one or more embodiments, the semiconductor structure 700 may include a second conductive layer 712 formed over the fill layer 710. In one or more embodiments, the second conductive layer 712 may be substantially flat.

As shown in FIG. 7B, a semiconductor structure 750 may include a workpiece 702 including at least one opening 704 (e.g. a hole, a cavity, a trench, or a via). In one or more embodiments, the semiconductor structure 750 may include a first conductive layer 706 (e.g. including a metal or a metal alloy) lining the at least one opening 704. In one or more embodiments, the semiconductor structure 750 may include a fill layer 710 formed within the at least one opening 704, wherein a top surface 710a of the fill layer 710 may be below a top surface 706a of a part 706b of the first conductive layer 706 outside the at least one opening 704. In one or more embodiments, the semiconductor structure 700 may include a second conductive layer 712 formed over the fill layer 710. In one or more embodiments, the top surface 710a of the fill layer 710 may be substantially flush with the top surface 706a of the first conductive layer 706 outside the at least one opening 704. In one or more embodiments, a height difference H between the top surface 710a of the fill layer 710 and the top surface 706a of the part 706b of the first conductive layer 706 outside the at least one opening 704 may be less than or equal to about half a thickness T2 of the part 706b of the first conductive layer 706 outside the at least one opening 704.

The thickness T2 may, for example, correspond to the thickness of the first conductive layer 706, which may, for example, be in the range from about 100 nm to about 10 μm. Therefore, in one or more embodiments, the height difference H between the top surface 710a of the fill layer 710 and the top surface 706a of the part 706b of the first conductive layer 706 outside the at least one opening 704 may be less than or equal to about 5 μm, for example less than or equal to about 2 μm, for example less than or equal to about 1 μm, for example less than or equal to about 800 nm, for example less than or equal to about 500 nm, for example less than or equal to about 400 nm, for example less than or equal to about 250 nm, for example less than or equal to about 100 nm, for example less than or equal to about 50 nm, for example less than or equal to about 10 nm, for example less than or equal to about 5 nm, for example less than or equal to about 2 nm, for example less than or equal to about 1 nm, although other values may be possible as well in accordance with other embodiments.

According to one or more embodiments, a method of forming a semiconductor structure may be provided. In one or more embodiments, the method may include: forming at least one opening in a workpiece; forming a first conductive layer within said at least one opening, said first conductive layer not completely filling said at least one opening; forming a fill layer over said first conductive layer within said at least one opening; and forming a second conductive layer over said fill layer.

In one or more embodiments, said second conductive layer may be at least substantially planar.

In one or more embodiments, said forming said at least one opening in said workpiece may include etching said workpiece.

In one or more embodiments, said forming said first conductive layer within said at least one opening may include forming said first conductive layer over at least one sidewall and a bottom surface of said at least one opening.

In one or more embodiments, said forming said first conductive layer within said at least one opening may further include forming said first conductive layer over a part of a top surface of said workpiece.

In one or more embodiments, said forming said first conductive layer within said at least one opening may include a deposition process.

In one or more embodiments, said deposition process may be a conformal deposition process.

In one or more embodiments, said forming said first conductive layer within said at least one opening may include a growth process.

In one or more embodiments, said forming said fill layer over said first conductive layer within said at least one opening may include depositing a fill material over said first conductive layer and recessing said fill material.

In one or more embodiments, said recessing said fill material may include recessing said fill material to expose a top surface of a part of said first conductive material outside said at least one opening.

In one or more embodiments, a top surface of said fill layer may be below a top surface of a part of said first conductive layer outside said at least one opening.

In one or more embodiments, a height difference between said top surface of said fill layer and said top surface of said part of said first conductive layer outside said at least one opening may be less than or equal to about half a thickness of said part of said first conductive layer outside said at least one opening.

In one or more embodiments, a top surface of said fill layer may be at least substantially flush with a top surface of a part of said first conductive layer outside said at least one opening.

In one or more embodiments, said forming said second conductive layer over said fill layer may include a deposition process.

In one or more embodiments, said forming said second conductive layer over said fill layer may include forming said second conductive layer over said fill layer and a part of said first conductive layer outside said at least one opening.

In one or more embodiments, the method may further include forming a dielectric layer over said second conductive layer.

In one or more embodiments, forming said dielectric layer over said second conductive layer may include forming said dielectric layer over said second conductive layer and a part of said workpiece free from said first conductive layer.

In one or more embodiments, forming said dielectric layer over said second conductive layer may include forming said dielectric layer over said second conductive layer and a part of said first conductive layer free from said second conductive layer.

In one or more embodiments, the method may further include forming at least one opening through said dielectric layer.

In one or more embodiments, said forming said at least one opening through said dielectric layer may include exposing a part of said second conductive layer disposed over said fill layer.

In one or more embodiments, said workpiece may include a dielectric material.

In one or more embodiments, said workpiece may include a semiconductor material.

In one or more embodiments, at least one of said first conductive layer and said second conductive layer may include a metal or metal alloy.

In one or more embodiments, said fill layer may include a dielectric material.

In one or more embodiments, said fill layer may include at least one material selected from a group of materials, said group consisting of: a resist material, an imide material, an oxide material, a nitride material, an oxynitride material, and benzocyclobutene.

In one or more embodiments, said fill layer may include a conductive material.

In one or more embodiments, said dielectric layer may include at least one material selected from a group of materials, said group consisting of: an oxide, a nitride and an oxynitride.

In one or more embodiments, an aspect ratio of said at least one opening in said workpiece may be greater than or equal to about 1.

In one or more embodiments, an aspect ratio of said at least one opening in said workpiece may be less than or equal to about 1.

According to one or more embodiments, a method of forming a semiconductor structure may be provided. In one or more embodiments, the method may include: forming at least one opening in a workpiece; depositing a first conductive layer over said workpiece to line at least one of a bottom surface and one or more sidewalls of said at least one opening with said first conductive layer; filling said at least one opening with a fill layer, wherein a top surface of said fill layer may be at least substantially flush with a top surface of a part of said first conductive layer outside said at least one opening; and forming a second conductive layer over said recessed fill layer.

According to one or more embodiments, a method of forming a semiconductor structure may be provided. In one or more embodiments, the method may include: forming at least one opening in a workpiece; depositing a first conductive layer over said workpiece to partially fill said at least one opening; depositing a fill layer over said workpiece to completely fill said at least one opening; recessing said fill layer to expose a top surface of a part of said first conductive layer outside said at least one opening and form a recessed fill layer inside said at least one opening, wherein a top surface of said recessed fill layer inside said at least one opening is at least substantially flush with said top surface of said part of said first conductive layer outside said at least one opening; and depositing a second conductive layer over said top surface of said recessed fill layer and said top surface of said exposed first conductive layer.

According to one or more embodiments, a semiconductor structure may be provided. In one or more embodiments, the semiconductor structure may include: a workpiece including at least one hole; a first conductive layer lining said at least one hole; a fill layer formed within said at least one hole, wherein a top surface of said fill layer may be at least substantially flush with a top surface of said first conductive layer outside said at least one hole; and a second conductive layer formed over said fill layer.

While various aspects of this disclosure have been particularly shown and described with reference to these aspects of this disclosure, it should be understood by those skilled in the art that various changes in form and detail may be made therein without departing from the spirit and scope of the disclosure as defined by the appended claims. The scope of the disclosure is thus indicated by the appended claims and all changes which come within the meaning and range of equivalency of the claims are therefore intended to be embraced.

1. A method of forming a semiconductor structure, comprising:
forming at least one opening in a workpiece;
forming a first conductive layer within said at least one opening, said first conductive layer not completely filling said at least one opening;
forming a fill layer over said first conductive layer within said at least one opening; and
forming a second conductive layer over said fill layer;
wherein the second conductive layer is substantially uniplanar.

2. (canceled)

3. The method of claim 1, wherein said forming said at least one opening in said workpiece comprises etching said workpiece.

4. The method of claim 1, wherein said forming said first conductive layer within said at least one opening comprises forming said first conductive layer over at least one sidewall and a bottom surface of said at least one opening.

5. The method of claim 4, wherein said forming said first conductive layer within said at least one opening further comprises forming said first conductive layer over a part of a top surface of said workpiece.

6. The method of claim 1, wherein said forming said first conductive layer within said at least one opening comprises a deposition process.

7. The method of claim 6, wherein said deposition process is a conformal deposition process.

8. The method of claim 1, wherein said forming said first conductive layer within said at least one opening comprises a growth process.

9. The method of claim 1, wherein said forming said fill layer over said first conductive layer within said at least one opening comprises depositing a fill material over said first conductive layer and recessing said fill material.

10. The method of claim 9, wherein said recessing said fill material comprises recessing said fill material to expose a top surface of a part of said first conductive material outside said at least one opening.

11. The method of claim 1, wherein a top surface of said fill layer is below a top surface of a part of said first conductive layer outside said at least one opening.

12. The method of claim 11, wherein a height difference between said top surface of said fill layer and said top surface of said part of said first conductive layer outside said at least one opening is less than or equal to about half a thickness of said part of said first conductive layer outside said at least one opening.

13. The method of claim 1, wherein a top surface of said fill layer is at least substantially flush with a top surface of a part of said first conductive layer outside said at least one opening.

14. The method of claim 1, wherein said forming said second conductive layer over said fill layer comprises a deposition process.

15. The method of claim 1, wherein said forming said second conductive layer over said fill layer comprises forming said second conductive layer over said fill layer and a part of said first conductive layer outside said at least one opening.

16. The method of claim 1, further comprising, forming a dielectric layer over said second conductive layer.

17. The method of claim 16, wherein forming said dielectric layer over said second conductive layer comprises forming said dielectric layer over said second conductive layer and a part of said workpiece free from said first conductive layer.

18. The method of claim 16, wherein forming said dielectric layer over said second conductive layer comprises forming said dielectric layer over said second conductive layer and a part of said first conductive layer free from said second conductive layer.

19. The method of claim 16, further comprising: forming at least one opening through said dielectric layer.

20. The method of claim 19, wherein said forming said at least one opening through said dielectric layer comprises exposing a part of said second conductive layer disposed over said fill layer.

21. The method of claim 1, wherein said workpiece comprises a dielectric material.

22. The method of claim 1, wherein said workpiece comprises a semiconductor material.

23. The method of claim 1, wherein at least one of said first conductive layer and said second conductive layer comprises a metal or metal alloy.

24. The method of claim 1, wherein said fill layer comprises a dielectric material.

25. The method of claim 1, wherein said fill layer comprises at least one material selected from a group of materials, said group consisting of: a resist material, an imide material, an oxide material, a nitride material, an oxynitride material, and benzocyclobutene.

26. The method of claim 1, wherein said fill layer comprises a conductive material.

27. The method of claim 16, wherein said dielectric layer comprises at least one material selected from a group of materials, said group consisting of: an oxide, a nitride and an oxynitride.

28. The method of claim 1, wherein an aspect ratio of said at least one opening in said workpiece is greater than or equal to about 1.

29. The method of claim 1, wherein an aspect ratio of said at least one opening in said workpiece is less than or equal to about 1.

30. A method of forming a semiconductor structure, comprising:
forming at least one opening in a workpiece;
depositing a first conductive layer over said workpiece to line at least one of a bottom surface and one or more sidewalls of said at least one opening with said first conductive layer;
filling said at least one opening with a fill layer, wherein a top surface of said fill layer is at least substantially flush with a top surface of a part of said first conductive layer outside said at least one opening;
forming a second conductive layer over said fill layer; and
wherein the second conductive layer is substantially uniplanar.

31. A method of forming a semiconductor structure, comprising:
forming at least one opening in a workpiece;
depositing a first conductive layer over said workpiece to partially fill said at least one opening;
depositing a fill layer over said workpiece to completely fill said at least one opening;
recessing said fill layer to expose a top surface of a part of said first conductive layer outside said at least one opening and form a recessed fill layer inside said at least one opening, wherein a top surface of said recessed fill layer inside said at least one opening is at least substantially flush with said top surface of said part of said first conductive layer outside said at least one opening; and
depositing a second conductive layer over said top surface of said recessed fill layer and said top surface of said exposed first conductive layer;
wherein the second conductive layer is substantially uniplanar.

32. A semiconductor structure, comprising:
a workpiece comprising at least one hole;
a first conductive layer lining said at least one hole;
a fill layer formed within said at least one hole, wherein a top surface of said fill layer is at least substantially flush with a top surface of said first conductive layer outside said at least one hole;
a second conductive layer formed over said fill layer;
wherein the second conductive layer is substantially uniplanar.
